(19) United States
(12) Patent Application Publication
(10) Pub. No.: US 2025/0132744 A1
(43) Pub. Date: Apr. 24, 2025

(54) ACOUSTIC WAVE DEVICE AND FABRICATING METHOD THEREOF

(71) Applicant: RichWave Technology Corp., Taipei City (TW)

(72) Inventor: Hao-Min Huang, Taipei City (TW)

(73) Assignee: RichWave Technology Corp., Taipei City (TW)

(21) Appl. No.: 18/510,669

(22) Filed: Nov. 16, 2023

(30) Foreign Application Priority Data
Oct. 18, 2023 (TW) 112139707

(51) Int. Cl. H03H 3/02; H03H 9/02

(52) U.S. Cl. CPC H03H 3/02; H03H 9/02086

(57) ABSTRACT

An acoustic wave device and a fabricating method are provided. The acoustic wave device includes a substrate, a first frame, a first electrode, a piezoelectric layer and a second electrode. The substrate includes a first surface and a second surface opposite thereto. A reflector recess and a first recess may be depressed from the first surface. The first recess may at least partially surround the reflector recess, and may be separated from the reflector recess. The first frame is disposed in the first recess of the substrate. The first electrode is disposed on the substrate and contacts the first frame. The piezoelectric layer is disposed at least on the first electrode. The second electrode is disposed at least on the piezoelectric layer. The reflector recess of the substrate, the first electrode, the piezoelectric layer, and the second electrode at least partially overlap along a vertical direction.

### TECHNICAL FIELD

The present invention relates to the field of acoustic wave, and in particular to an acoustic wave device and a fabricating method of the same.

### BACKGROUND

Bulk acoustic waves (BAW) devices may be used to convert and transceive electrical signals and/or acoustic signals. The BAW devices may be widely applicable to fields such as electrical communications, global positioning system (GPS), and military uses. The BAW devices may be used to configure BAW filters, which may filter out noises from wireless signals so as to achieve a desired band of frequency and result in advantages such as lower transmission loss, stronger ability to avoid interference from electromagnetic, and/or a compact size. In addition, SAW devices may also be implemented in resonators. A BAW device may generate a spurious mode, which may cause undesirable energy leakage and performance degradation.

### SUMMARY

According to an embodiment of the invention, an acoustic wave device includes a substrate, a frame, a first electrode, a piezoelectric layer and a second electrode. The substrate includes a first surface, a second surface opposite to the first surface, a reflector recess depressed from the first surface, and a first recess depressed from the first surface. The first recess at least partially surrounds the reflector recess and is separated from the reflector recess. The first frame is disposed in the first recess of the substrate. The first electrode is disposed on the substrate and contacting the first frame. The piezoelectric layer is disposed at least on the first electrode. The second electrode is disposed at least on the piezoelectric layer. The reflector recess of the substrate, the first electrode, the piezoelectric layer, and the second electrode at least partially overlap in a vertical direction.

According to another embodiment of the invention, a fabricating method of an acoustic wave device includes providing a substrate, forming a reflector in the substrate, forming a first recess in the substrate, and forming a first frame in the first recess. The first recess at least partially surrounds the reflector and is separated from the reflector. The method further includes forming a first electrode on the substrate, and the first electrode is configured to contact the first frame. The method further includes forming a piezoelectric layer at least on the first electrode and forming a second electrode at least on the piezoelectric layer. The reflector of the substrate, the first electrode, the piezoelectric layer, and the second electrode at least partially overlap in a vertical direction.

According to another embodiment of the invention, a fabricating method of an acoustic wave device includes provide a substrate, forming a reflector recess in the substrate, filling the reflector recess with a sacrificial material, forming a first recess in the substrate, and forming a first frame in the first recess. The first recess at least partially surrounds the reflector recess and is separated from the reflector recess. The method further includes forming a first electrode on the substrate, and the first electrode is configured to contact the first frame and is at least on the sacrificial material. The method further includes forming a piezoelectric layer at least on the first electrode and forming a second electrode at least on the piezoelectric layer. The sacrificial material in the reflector recess, the first electrode, the piezoelectric layer, and the second electrode at least partially overlap in a vertical direction.

### BRIEF DESCRIPTION OF THE DRAWINGS

FIG. 1 is a schematic cross-sectional view of an acoustic wave device according to an embodiment of the invention.

FIG. 2 is a schematic top view of an exemplary configuration of a reflector recess and a first recess according to an embodiment of the invention.

FIG. 3 is a schematic top view of another exemplary configuration of the reflector recess and a first recess according to another embodiment of the invention.

FIG. 4 is a schematic cross-sectional view of an acoustic wave device according to another embodiment of the invention.

FIG. 5 is a schematic flowchart of a fabricating method of an acoustic wave device according to an embodiment of the invention.

FIG. 6 to FIG. 9 schematically show steps of a fabricating method of an acoustic wave device according to an embodiment of the invention.

FIG. 10 is a schematic flowchart of another fabricating method of an acoustic wave device according to another embodiment of the invention.

### DETAILED DESCRIPTION

Below, exemplary embodiments will be described in detail with reference to accompanying drawings so as to be easily realized by a person having ordinary knowledge in the art. The inventive concept may be embodied in various forms without being limited to the embodiments set forth herein. Descriptions of well-known parts may be omitted for clarity, and like reference numerals refer to like elements throughout.

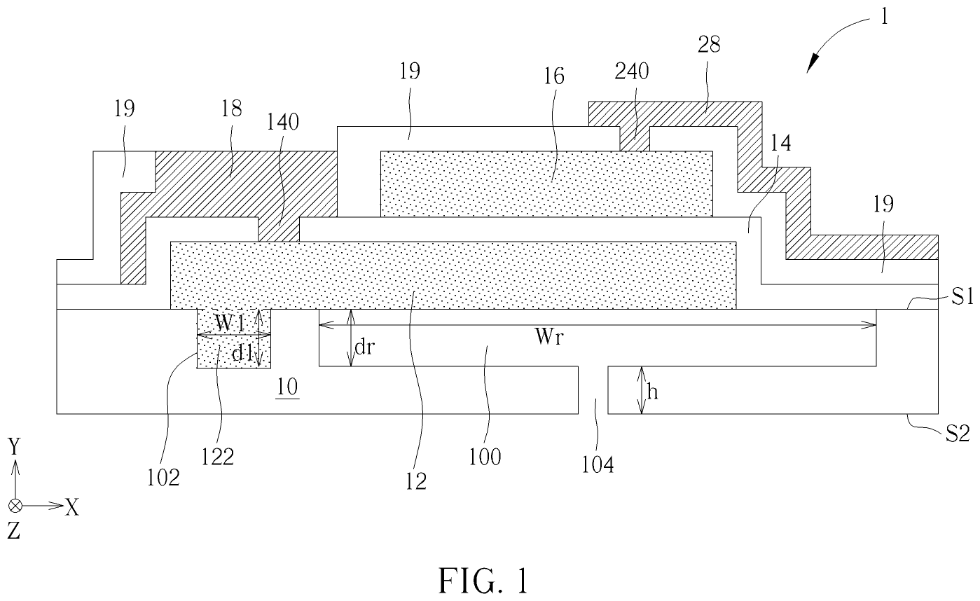

FIG. 1 is a schematic cross-sectional view of an acoustic wave device 1 according to an embodiment of the invention. The acoustic wave device 1 may include a bulk acoustic wave (BAW) device, and may implemented for a resonator, a filter or other radio frequency devices. In some embodiments, the acoustic wave device 1 may be used for a BAW resonator, which may be configured to receive an input signal, generate an acoustic wave, and convert the acoustic wave into a resonant signal. In other embodiments, the acoustic wave device 1 may be implemented for a BAW filter, which may be configured to receive an input signal from e.g., an antenna, filter the received signal based on a frequency selectivity, and allow signals with desired frequencies to pass. Various applications of the acoustic wave device 1 may be provided above for illustrative description without limiting.

In some embodiments, the acoustic wave device 1 may include a substrate 10, a frame 122, an electrode 12, a piezoelectric layer 14 and an electrode 16. In operation, the electrode 16 may be used to receive an input signal, and the electrode 12 may be grounded to generate an acoustic wave propagating along a vertical direction Y. The piezoelectric layer 14 may be used to convert the acoustic wave into a resonant signal with a resonant frequency. The resonant frequency may be determined depending on various parameters of the acoustic wave device 1, such as the material and/or thickness of the piezoelectric layer 14, the weights of the electrode 12 and/or the electrode 16, etc. For example, the resonant frequency may range from 100 megahertz (MHz) to 20 gigahertz (GHz). The material of the substrate 10 may include silicon, glass, ceramic, gallium arsenide, and/or silicon carbide.

In some embodiments, the substrate 10 may include a surface S1, a surface S2, a reflector recess 100, and a first recess 102. As shown in FIG. 1, the surface S1 and the surface S2 of substrate 10 may be opposite to each other. The reflector recess 100 and the first recess 102 may be depressed from the surface S1, and the first recess 102 may be configured to at least partially surround the reflector recess 100 and be separated from the reflector recess 100.

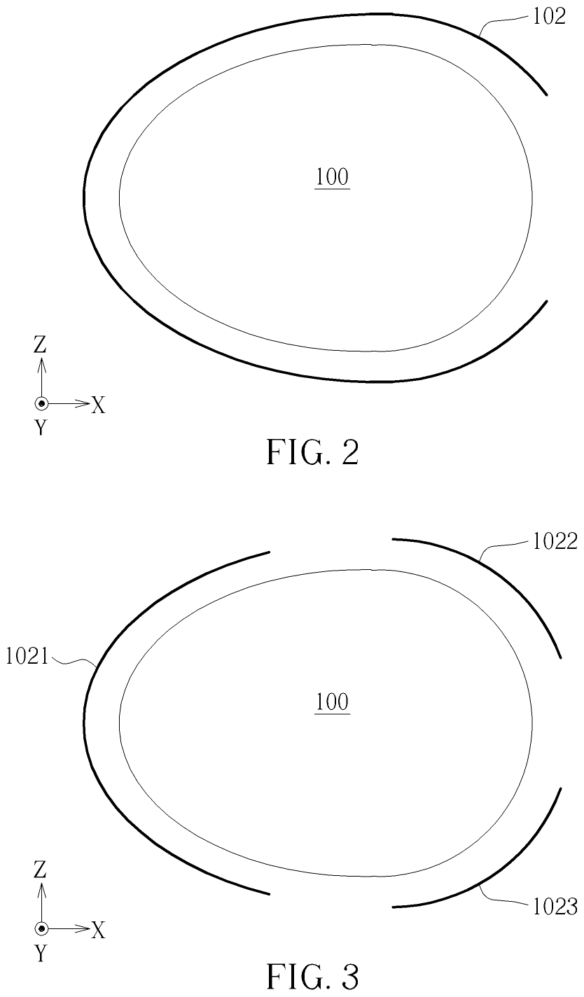

FIG. 2 and FIG. 3 are schematic top views of exemplary configurations of the reflector recess 100 and the first recess 102 according to at least one embodiment of the invention. The outline of the reflector recess 100 may be, but is not limited to, egg-shaped. In other embodiments, the outline of the reflector recess 100 may be other shapes such as a square, a circle, a pentagon, or other regular or irregular shapes.

In FIG. 2, the reflector recess 100 may be e.g., egg-shaped, and the first recess 102 may be configured to substantially surround the reflector recess 100 continuously, e.g., surrounding more than 50% of the periphery of the reflector recess 100. For example, the first recess 102 may continuously surround near a narrow portion of the egg-shaped reflector recess 100, and may also surround along two side portions of the reflector recess 100, with an opening located near a wide portion of the egg-shaped reflector recess 100. Thus, the first recess 102 is configured to partially surround the reflector recess 100. In other embodiments, the opening of the first recess 102 may be located at different positions from what shown in FIG. 2 and may have different sizes. For example, the first recess 102 may have an opening located near the narrow portion or at one of the side portions of the egg-shaped reflector recess 100. In some embodiments, the first recess 102 may entirely surround the egg-shaped reflector recess 100.

In FIG. 3, the reflector recess 100 may be e.g. egg-shaped, and the first recess 102 may be configured to substantially surround the reflector recess 100 discontinuously. For example, the first recess 102 may include three portions 1021, 1022 and 1023. For example, the portion 1021 may be provided near the narrow portion of the egg-shaped reflector recess 100, and the portions 1022 and 1033 may both be provided near two side portions and/or the wide portion of the reflector recess 100. In some embodiments, the first recess 102 may include more portions surrounding around the reflector recess 10. In the above embodiments, the illustrated egg-shape is merely for illustrative purposes and not intended to limit the present invention. In some embodiments, the reflector recess may be configured to have other outlines or shapes.

In FIG. 1, the frame 122 may be disposed in the first recess 102 of the substrate 10. In other words, the first recess 102 may be filled with the frame 122. The electrode 12 may be disposed on the surface S1 of the substrate 10 and may contact the frame 122. Moreover, the piezoelectric layer 14 may be disposed at least on the electrode 12, and the electrode 16 may be disposed at least on the piezoelectric layer 14. The reflector recess 100 of the substrate 10 may be used to form an air cavity below the electrode 12 and the air cavity may act as a reflector of the acoustic wave device 1. For example, the material of the electrodes 12 and/or 16 may include conductive materials such as molybdenum (Mo), copper (Cu), aluminum (Al), gold (Au), platinum (Pt), tungsten (W), other suitable metals or a combination thereof. The material of the piezoelectric layer 14 may include, for example, at least one of the followings: zinc oxide (ZnO), aluminum nitride (AlN), lithium tantalate (LiTaO₃, LT), lithium niobate (LN), quartz (QZ), lead titanate (PTO), lead zirconate titanate (PZT), other materials or a combination thereof. In some embodiments, the piezoelectric layer 14 may be doped with a rare earth element such as scandium (Sc).

Further, the material of the frame 122 may be a conductive material or a non-conductive material. In some embodiments, the material of the frame 122 may be the same as the material of the electrode 12, such as Mo. In the embodiment, the frame 122 and the electrode 12 may be monolithically integrated or formed. For example, the frame 122 and the electrode 12 may be formed in a same step. However, in other embodiments, the material of the frame 122 may be different from the material of the electrode 12. For example, the material of the frame 122 may be W, and the material of the electrode 12 may be Mo. For example, the material of the frame 122 may be selected to have a density higher than that of the electrode 12, thereby reducing or preventing the leakage of acoustic waves propagating along a horizontal direction X, so as to suppress a spurious mode. In other embodiments, the material of the frame 122 may be dielectric material. The horizontal direction may be, for example, a direction parallel to the surface S1, and the material density may be defined as, for example, mass per unit volume. For example, the density of aluminium is about 2.90 g/cm³, the density of Mo is about 10.2 g/cm³, and/or the density of W is about 19.25 g/cm³.

In FIG. 1, along the vertical direction Y (i.e., the direction perpendicular to the surface S1), the reflector recess 100 of the substrate 10, the electrode 12, the piezoelectric layer 14, and the electrode 16 may at least partially overlap. The overlapping area of the reflector recess 100, the electrode 12, the piezoelectric layer 14, and the electrode 16 may be referred to as an active area, and acoustic waves may propagate along the vertical direction Y in the active area.

In the substrate 10, the first recess 102 may have a dimension W1 along the horizontal direction X and a depth d1 along the vertical direction Y. The reflector recess 100 may have a dimension Wr (also referred to as a reflector dimension) along the horizontal direction X and a depth dr (also referred to as a reflector depth) along the vertical direction Y. For example, the depth d1 of the first recess 102 may be measured from the surface S1 of the substrate 10 to the bottom of the first recess 102, and the depth dr of the reflector recess 100 may be measured from the surface S1 of the substrate 10 to the bottom of the reflector recess 100. The size W1 of the first recess 102 may be less than the Wr of the reflector recess 100. In FIG. 1, the depth d1 of the first recess 102 and the depth dr of the reflector recess 100 may be equal (d1=dr), but the present invention is not limited thereto. In other embodiments, the depth of the first recess 102 d1 may be different from the depth dr of the reflector recess 100 (d1≠dr). For example, the depth d1 of the first recess 102 may be greater than the depth dr of the reflector recess 100 (d1>dr). In other words, the first recess 102 may be deeper than the reflector recess 100, resulting in a thicker frame 122 around the reflection recess 100, so as to thereby further suppress a spurious mode.

The substrate 10 may further include a through hole 104, and the through hole 104 may be configured to communicate from the surface S2 of the substrate 10 to the reflector recess 100. The height h of the through hole 104 may be ranged between 150 micrometers and 200 micrometers. As described in further detail below, the through hole 104 may be used to facilitate removing a sacrificial material during fabrication. Since the through hole 104 is provided at a bottom surface of the substrate 10 (e.g., the surface S2), various materials on the front surface (such as, the surface S1) may be avoided from being interfered, and there may be more region available for layout on the front surface. Therefore, an undesirable impact resulted from a through hole at the front surface on the resonant frequency of the acoustic wave device 1 may be reduced or eliminated.

As described above, an air cavity formed by the reflector recess 100 of the substrate 10 may act as a reflector of the acoustic wave device 1. In other embodiments, the reflector may be implemented in other forms. For example, a plurality of stacked layers may be provided in the reflector recess 100. The plurality of stacked layers may at least include a first layer having a first acoustic wave impedance, and a second layer stacked on the first layer. The second layer may have a second acoustic wave impedance and the first acoustic impedance may be less than the second acoustic impedance. In this embodiment, the reflector formed by the plurality of stacked layers may also be referred to as a Bragg reflector, which may also be used to reduce or prevent acoustic wave leakage and suppress a spurious mode. Specifically, the first layer and the second layer of the plurality of stacked layers may be layers of different material. Alternatively, the first layer and the second layer may contain substantially the same main material, but the two layers may respectively include different dopants. Further, the first layer and the second layer may be substantially identical in the main material and the dopant therein, while be different in dopant concentration, so as to achieve different refractive indexes for acoustic waves.

In some embodiments, the acoustic wave device 1 may further include a passivation layer 19, and the passivation layer 19 may at least partially cover on the upper electrode such as the electrode 16, thereby protecting the upper electrode 16 and the materials below. For example, the material of the passivation layer 19 may include silicon oxide or silicon nitride. The acoustic wave device 1 may further include a contact 18, and the contact 18 may be electrically connected to a lower electrode such as the electrode 12 via a contact hole 140 in the piezoelectric layer 14. In FIG. 1, the contact hole 140 may pass through the piezoelectric layer 14, and the contact 18 may cover on the piezoelectric layer 14. The contact 18 may physically contact the electrode 12 via the contact hole 140 in the piezoelectric layer 14. In the embodiment, the material of the contact 18 may include a conductive material such as tin, gold, or aluminum-copper alloy (Al—Cu). In some embodiments, the contact hole 140 of the piezoelectric layer 14 may be omitted, and the contacts 18 may be electrically connected to the electrodes 12 in other ways. The passivation layer 19 may further cover on the contact 18 and the piezoelectric layer 14. As discussed further below, the acoustic wave device 1 may further include a contact 28 electrically connected to the electrode 16.

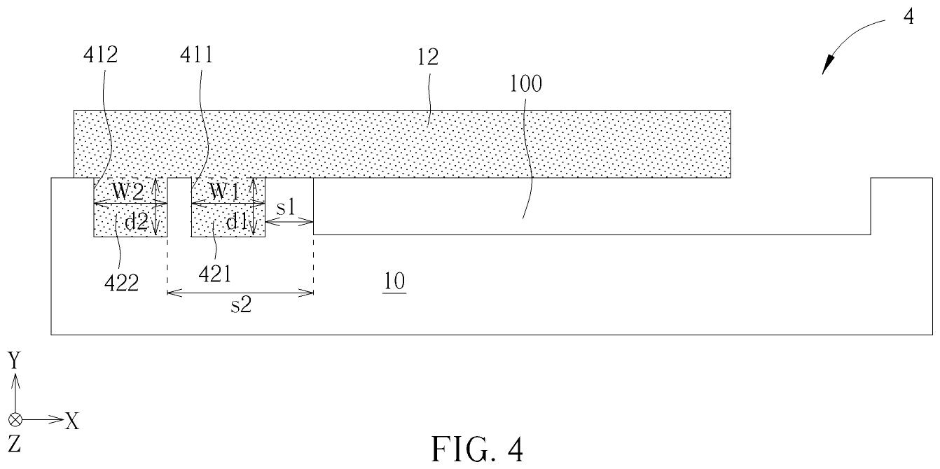

FIG. 4 is a schematic cross-sectional view of an acoustic wave device 4 according to another embodiment of the invention. The acoustic wave device 4 and the acoustic wave device 1 may be different in that the substrate 10 of the acoustic wave device 4 includes two recesses 411 and 412. Two frames 421 and 422 may be respectively disposed in the two recesses 411 and 412. The differences between the acoustic wave devices 4 and 1 will be explained below in detail. Similar structures of the acoustic wave device 4 and the acoustic wave device 1 may not be explained herein.

The substrate 10 may include the first recess 411 and the second recess 412, both depressed from the surface S1 of the substrate 10 and at least partially surrounding the reflector recess 100. The first recess 411 and the second recess 412 may both be separated from the reflector recess 100. Further, the first recess 411 and the second recess 412 may be separated from each other. For example, in the horizontal direction X, the first recess 411 may be separated from the reflective recess 100 by a first distance s1, the second recess 412 may be separated from the reflective recess 100 by a second distance s2, and s2 may be greater than s1. The acoustic wave device 4 may include the first frame 421 and the second frame 422, the first frame 421 may be filled in the first recess 411, and the second frame 422 may be filled in the second recess 412. In the embodiment, both the first frame 421 and the second frame 422 may, but is not limited to, contact the electrode 12. In other embodiments, the second frame 422 may not contact the electrode 12 and it may instead contact the electrode 16. Alternatively, the second frame 422 does not contact the electrode 12 or the electrode 16.

In some embodiments, the first frame 421 and the second frame 422 may be made of different materials. For example, the first frame 421 may be made of a metal material, and the second frame 422 may be made of a dielectric material. Compared to the embodiment in FIG. 1, the second frame 422 may be additionally provided in FIG. 4, and thus may form an additional weight load around the active area, thereby further reducing or preventing the acoustic wave leaks along the horizontal direction X and/or suppressing a spurious mode.

In the substrate 10, the first recess 411 may have a dimension W1 along the horizontal direction X and a depth d1 along the vertical direction Y, and the second recess 412 may have a dimension W2 along the horizontal direction X and a depth d2 along the vertical direction Y. In some embodiments, the depth d1 of the first recess 411 and the depth d2 of the second recess 412 may be equal (d1=d2). In other embodiments, the depth d1 of the first recess 411 and the depth d2 of the second recess 412 may be different (d1/d2), and for example, d1 may be less than d2. In some embodiments, the dimension W1 of the first recess 411 and the dimension W2 of the second recess 412 may be equal (W1=W2). In other embodiments, the dimension W1 of the first recess 411 and the dimension W2 of the second recess 412 may be different (W1/W2), and for example, W1 may be greater than W2.

Although FIG. 4 shows two recesses and two frames, those skilled in the art may adjust the numbers and/or the positions of the recesses and the frames as desired without deviating from the principle of the invention. For example, the acoustic wave device may be provided with three recesses and three frames. Furthermore, in the embodiments in FIG. 4 and FIG. 2, the number of recesses may be the equal to that of the frame, but the present invention is not limited thereto. In other embodiments, the number of recesses may exceed that of the frame, in other words, there may be at least one recess in which no frame may be provided.

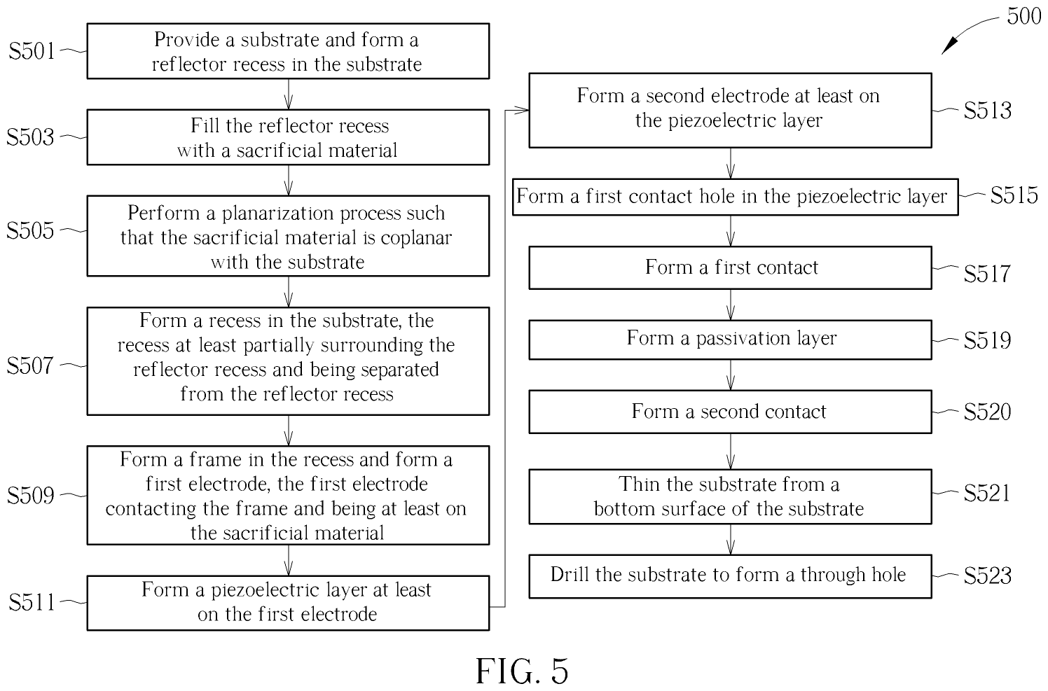

FIG. 5 is a schematic flowchart of a fabricating method 500 of an acoustic wave device. The method 500 may include steps S501 to S523 for fabricating an acoustic wave device 1. Any reasonable step change or adjustment may be within the scope of the disclosure. Steps S501 to S523 may be detailed as follows:

Step S501: Provide a substrate 10 and form a reflector recess 100 in the substrate 10; Step S503: Fill the reflector recess 100 with a sacrificial material 70;

Step S505: Perform a planarization process till the sacrificial material 70 is coplanar with the substrate 10;

Step S507: Form a recess 102 in the substrate 10, the recess 102 at least partially surrounding the reflector recess 100 and being separated from the reflector recess 100;

Step S509: Form a frame 122 in the recess 102 and form a first electrode 12. The first electrode 12 contacts the frame 122, and the first electrode 12 is at least on the sacrificial material 70;

Step S511: Form a piezoelectric layer 14 at least on the first electrode 12; Step S513: Form a second electrode 16 at least on the piezoelectric layer 14;

Step S515: Form a first contact hole 140 in the piezoelectric layer 14;

Step S517: Form a first contact 18 electrically connected to the first electrode 12 via the first contact hole 140;

Step S519: Form a passivation layer 19 at least covering on the second electrode 16;

Step S520: Form a second contact 28. The second contact 28 may be electrically connected to the second electrode 16 via the second contact hole 240, and the second contact hole 240 may be formed in the passivation layer 19;

Step S521: Thin the substrate 10 from a bottom surface of the substrate 10;

Step S523: Drill the substrate 10 from the surface S2 of the substrate 10 to form a through hole 104, and the through hole 104 may be configured to communicate from the surface S2 to the reflector recess 100. The sacrificial material 70 may be removed through the through hole 104.

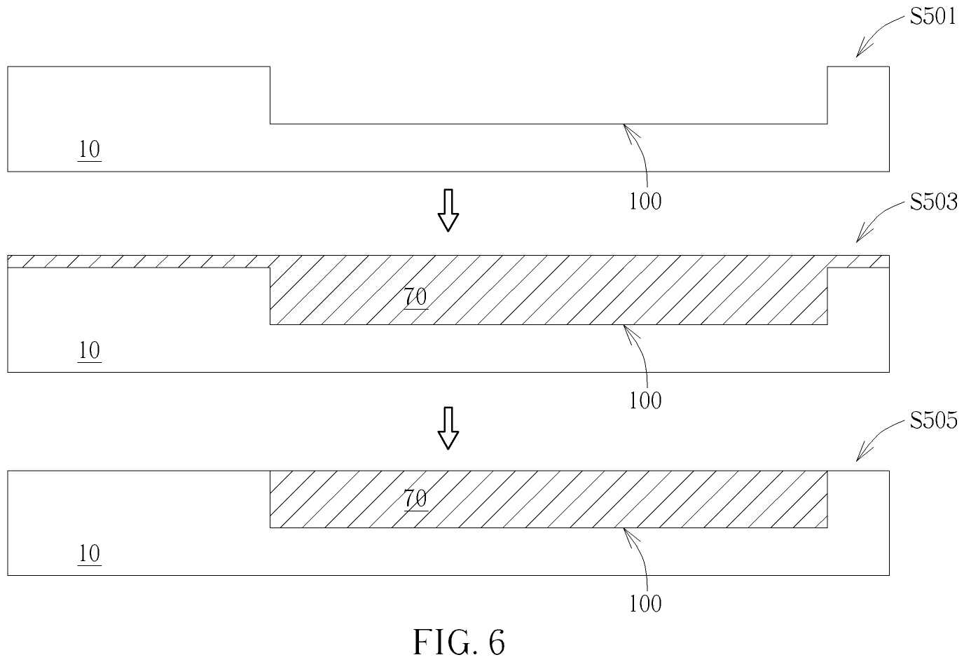

The fabricating method 500 may now be explained in detail with reference to FIG. 6 to FIG. 9.

FIG. 6 schematically shows steps S501 to S505. In Step S501, a substrate 10 may be provided and etched, for example, to form a reflector recess 100. In Step S503, the reflector recess 100 may be filled with a sacrificial material 70. The sacrificial material 70 may be e.g. silicon dioxide. In Step S503, a planarization process such as a chemical mechanical polishing/planarization (CMP) may be performed on the sacrificial material 70 such that the sacrificial material 70 may be coplanar with the substrate 10.

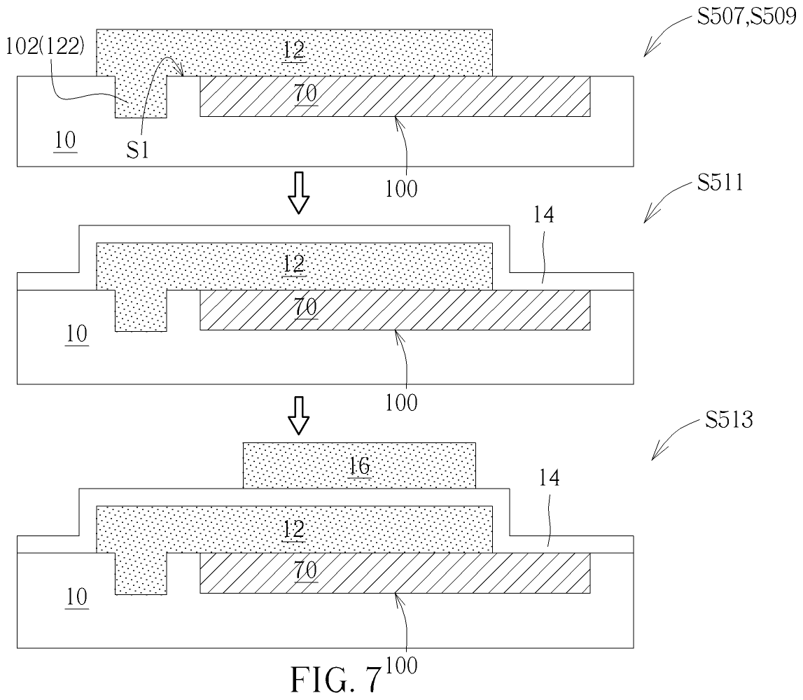

FIG. 7 schematically shows steps S507 to S513. In Step S507, a recess 102 may be formed in the substrate 10. For example, the substrate 10 may be further etched to form the recess 102, and the recess 102 may at least partially surround the reflector recess 100 and may be separated from the reflector recess 100. Next, in Step S509, the recess 102 may be filled with a material (e.g., a metal material) to form a frame 122, and for example, the metal material may also be deposited on the sacrificial material 70 simultaneously so as to form an electrode 12. In one example, the frame 122 and the electrode 12 may be monolithically formed. The electrode 12 may include a portion covering on the sacrificial material 70, a portion covering on the surface S1 of the substrate 10, and a portion contacting the frame 122. In other embodiments, the frame 122 and the electrode 12 may be formed separately. For example, a first metal material may be deposited in the recess 102 to form the frame 122, then a second metal material may be deposited on the frame 122, the sacrificial material 70, and the substrate 10 to form the electrode 12, and the first metal material and the second metal material may be different. In Step S511, a piezoelectric material may be deposited on the substrate 10, the electrode 12 and the sacrificial material 70 to form a piezoelectric layer 14. In Step S513, a metal material may be deposited on the piezoelectric layer 14 to form an electrode 16.

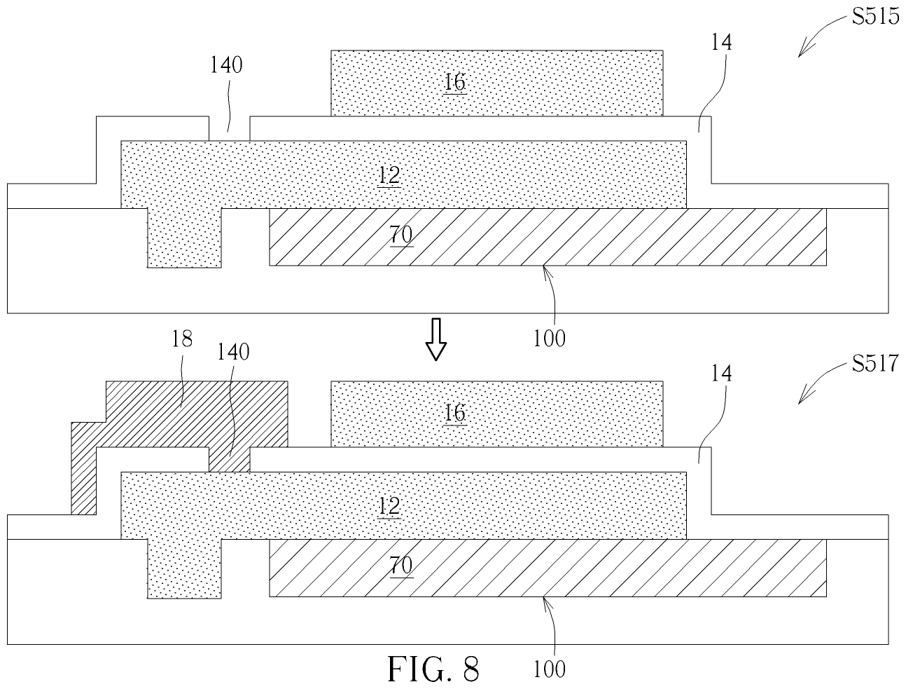

FIG. 8 schematically shows steps S515 and S517. In Step S515, a first contact hole 140 may be formed in the piezoelectric layer 14. For example, the piezoelectric layer 14 may be plasma etched to form the first contact hole 140. Next, in Step S517, a metal material may be deposited to form a first contact 18. The first contact 18 may be electrically connected to the electrode 12 via the first contact hole 140 and may be separated from the electrode 16 without being electrically connected to the electrode 16.

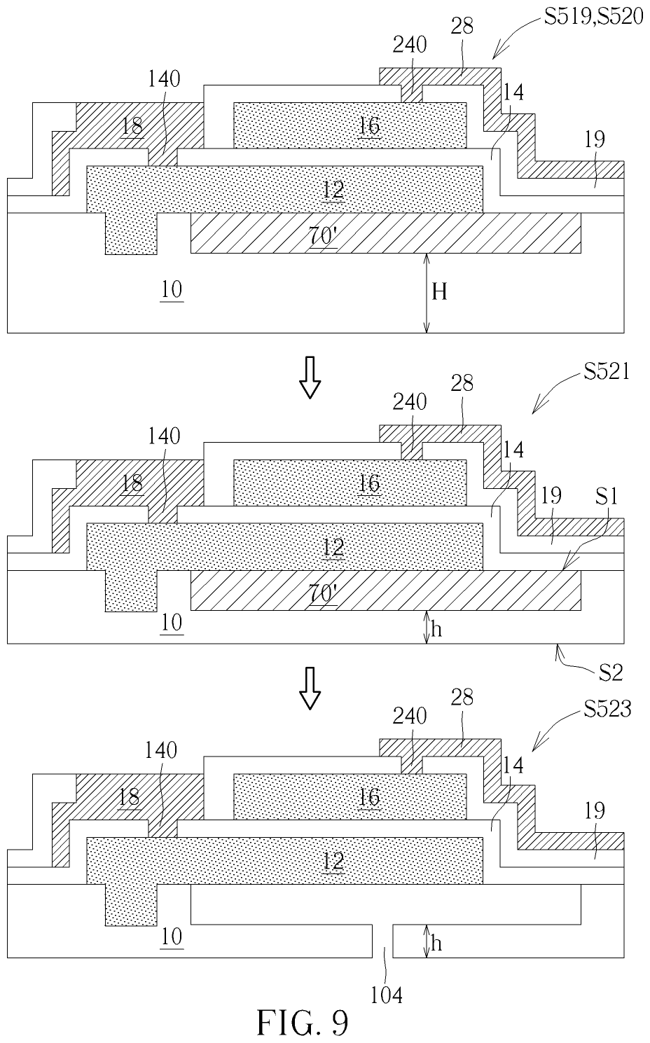

FIG. 9 schematically shows steps S519 to S523. In Steps S519-S520, a passivation layer 19 may be formed to at least cover on the electrode 16. A second contact hole 240 may be formed in the passivation layer 19, and a second contact 28 may be formed to electrically connect to the electrode 16 via the second contact hole 240. In Step S521, the substrate 10 may be thinned from a backside thereof, such that the thickness of the substrate 10 below the reflector recess 100 may be reduced from H to h, and the thickness h may be ranged between 150 micrometers and 200 micrometers. In Step S523, the substrate 10 may be drilled from the back surface to form a through hole 104, the through hole 104 may be configured to communicate to the reflector recess 100, and the sacrificial material 70 in the reflector recess 100 may be removed via the through hole 104.

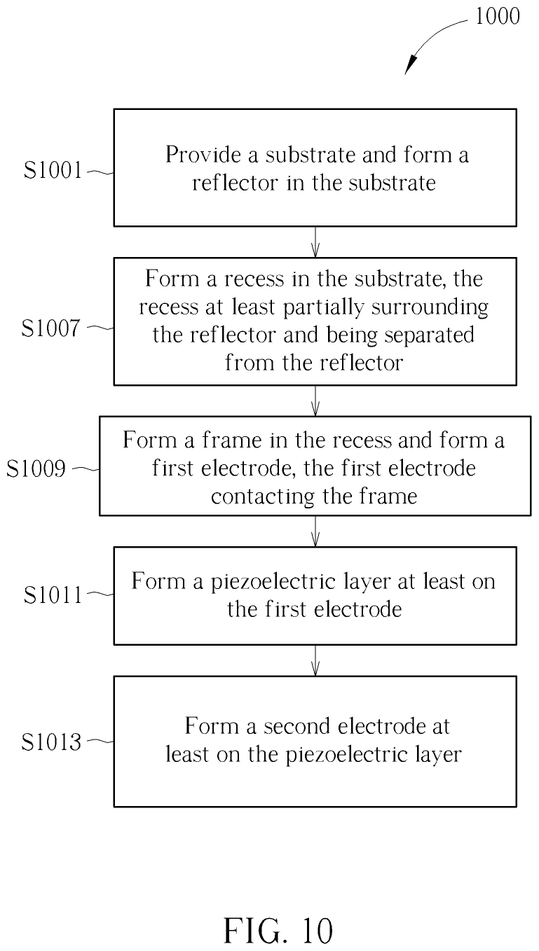

FIG. 10 is a schematic flowchart of another fabricating method 1000 of an acoustic wave device according to an embodiment of the invention. The fabricating method 1000 may include steps S1001 to S1013 for fabricating an acoustic wave device. Any reasonable step change or adjustment may be within the scope of the disclosure. Steps S1001 to S1013 may be detailed as follows:

Step S1001: Provide a substrate 10 and form a reflector 100 in the substrate 10. The reflector 100 may include an air cavity or a plurality of stacked layers;

Step S1007: Form a recess 102 in the substrate 10, the recess 102 at least partially surrounding the reflector and being separated from the reflector;

Step S1009: Form a frame 122 in the recess 102 and form a first electrode 12. The first electrode 12 contacts the frame 122;

Step S1011: Form the piezoelectric layer 14 at least on the first electrode 12;

Step S1013: Form the second electrode 16 at least on the piezoelectric layer 14.

The embodiments of the invention discloses the acoustic wave devices and the fabricating method of the same by forming a frame at the edge of the electrode to reduce or prevent the leakage of acoustic waves in the horizontal direction, suppressing the spurious mode and enhancing the circuit performance.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. An acoustic wave device comprising:
a substrate comprising:
a first surface;
a second surface opposite to the first surface;
a reflector recess depressed from the first surface; and
a first recess depressed from the first surface, the first recess at least partially surrounding the reflector recess and being separated from the reflector recess;
a first frame disposed in the first recess of the substrate;
a first electrode disposed on the substrate and contacting the first frame;
a piezoelectric layer disposed at least on the first electrode; and
a second electrode disposed at least on the piezoelectric layer, wherein the reflector recess of the substrate, the first electrode, the piezoelectric layer, and the second electrode at least partially overlap in a vertical direction.

2. The acoustic wave device of claim 1, further comprising a reflector disposed in the reflector recess, wherein the reflector comprises at least one of the followings: an air cavity and a plurality of stacked layers.

3. The acoustic wave device of claim 1, wherein the first recess has a first dimension along a horizontal direction and a first depth along the vertical direction, and the reflector recess has a reflector dimension along the horizontal direction and a reflector depth along the vertical direction, wherein the first dimension of the first recess is less than the reflector dimension of the reflector recess.

4. The acoustic wave device of claim 3, wherein the first depth of the first recess differs from the reflector depth of the reflector recess.

5. The acoustic wave device of claim 1, wherein the substrate further comprises:
a second recess depressed from the first surface, the second recess at least partially surrounding the reflector recess and being separated from the reflector recess, wherein
the first recess is separated from the reflector recess by a first distance in a horizontal direction, and the second recess is separated from the reflector recess by a second distance in the horizontal direction, wherein the second distance is greater than the first distance.

6. The acoustic wave device of claim 5, wherein the first recess has a first dimension along the horizontal direction and a first depth along the vertical direction, and the second recess has a second dimension along the horizontal direction and a second depth along the vertical direction, wherein the first depth of the first recess is different from the second depth of the second recess.

7. The acoustic wave device of claim 6, wherein the first dimension of the first recess is different from the second dimension of the second recess.

8. The acoustic wave device of claim 1, wherein a material of the first frame is different from a material of the first electrode.

9. The acoustic wave device of claim 1, wherein a material density of the first frame is higher than a material density of the first electrode.

10. The acoustic wave device of claim 1, wherein the first frame and the first electrode are monolithically integrated.

11. The acoustic wave device of claim 1, wherein the substrate further comprises a through hole configured to communicate from the second surface of the substrate to the reflector recess.

12. The acoustic wave device of claim 1, further comprising:
a first contact, configured to cover on the piezoelectric layer and to be electrically connected to the first electrode via a contact hole passing through the piezoelectric layer.

13. A fabricating method of an acoustic wave device, the method comprising:
providing a substrate;
forming a reflector in the substrate;
forming a first recess in the substrate, the first recess at least partially surrounding the reflector and being separated from the reflector;
forming a first frame in the first recess;
forming a first electrode on the substrate, the first electrode contacting the first frame;
forming a piezoelectric layer at least on the first electrode; and
forming a second electrode at least on the piezoelectric layer;
wherein the reflector of the substrate, the first electrode, the piezoelectric layer, and the second electrode at least partially overlap in a vertical direction.

14. A fabricating method of an acoustic wave device, the method comprising:
provide a substrate;
forming a reflector recess in the substrate;
filling the reflector recess with a sacrificial material;
forming a first recess in the substrate, the first recess at least partially surrounding the reflector recess and being separated from the reflector recess;
forming a first frame in the first recess;
forming a first electrode on the substrate, the first electrode contacting the first frame and being at least on the sacrificial material;
forming a piezoelectric layer at least on the first electrode; and
forming a second electrode at least on the piezoelectric layer;
wherein the sacrificial material in the reflector recess, the first electrode, the piezoelectric layer, and the second electrode at least partially overlap in a vertical direction.

15. The method of claim 14, further comprising:
after the step of filling the reflector recess with the sacrificial material, performing a planarization process till the sacrificial material is coplanar with the substrate.

16. The method of claim 14, further comprising:
thinning the substrate from a backside of the substrate;
drilling the substrate to form a through hole communicating to the reflector recess; and
removing the sacrificial material via the through hole.

17. The method of claim 14, further comprising:
forming a second recess in the substrate, the second recess at least partially surrounding the reflector recess and being separated from the reflector recess;
wherein the first recess is separated from the reflector recess by a first distance in a horizontal direction, the second recess is separated from the reflector recess by a second distance in the horizontal direction, and the second distance is greater than the first distance.

18. The method of claim 14, further comprising:
forming a first contact electrically connected to the first electrode.

19. The method of claim 14, further comprising:
forming a second contact electrically connected to the second electrode.

20. The method of claim 14, further comprising:
forming a passivation layer to at least cover on the second electrode.
